(19) United States
(12) Patent Application Publication
(10) Pub. No.: US 2017/0194539 A1
(43) Pub. Date: Jul. 6, 2017

(54) Layered Polymer Structures And Methods

(71) Applicant: Dow Corning Corporation, Midland, MI (US)

(72) Inventors: JODY J. HENNING, SAGINAW, MI (US); STEVEN SWIER, MIDLAND, MI (US)

(73) Assignee: Dow Corning Corporation, Midland, MI (US)

(21) Appl. No.: 15/316,670

(22) PCT Filed: Jun. 25, 2015
(86) PCT No.: PCT/US2015/037617

§ 371 Date: Dec. 6, 2016

Related U.S. Application Data
(60) Provisional application No. 62/016,959, filed on Jun. 25, 2014.

(51) Int. Cl. H01L 33/56; B32B 27/08; C08J 5/18; B32B 27/28

(52) U.S. Cl. CPC H01L 33/56; B32B 27/283; B32B 27/08; C08J 5/18; H01L 2224/73265; H01L 2224/48091; H01L 2924/181; H01L 2224/48227; B32B 2551/08; B32B 2307/418; B32B 2307/402; B32B 2307/748; B32B 2307/412

(57) ABSTRACT

An optical assembly includes an optical device having an optical surface. The optical assembly further includes an encapsulant. The encapsulant substantially covers the optical surface. In some embodiments, the encapsulant is pre-formed.

This disclosure generally relates to a layered polymeric structures and associated methods.

Optical devices, such as optical emitters, optical detectors, optical amplifiers, and the like, may emit or receive light via an optical surface. For various such devices, the optical surface may be or may include an electronic component or other component that may be sensitive to environmental conditions (e.g., rain, snow, and heat). For example, certain optical devices such as optoelectronics generally, including light emitting diodes (LEDs), laser diodes, and photosensors, can include solid state electronic components that may be susceptible to electrical shorts or other damage from environmental conditions if not protected. Even optical devices that may not be immediately susceptible may degrade over time if not protected. For example, an optical assembly that includes one or more optical devices may utilize a layered polymeric structure as an encapsulant for protection from environmental factors, as a lens, as a source of phosphor, and for other purposes. Substances that may be utilized as a layered polymeric structure for an optical device may tend to degrade over time. While such layered polymeric structures may start relatively clear, for instance, deterioration may result in cloudiness, yellowing, or other color distortion, causing a reduction or distortion in light emitted or detected from the optical device. Other forms of breakdown, such as cracking, warping, and the like, may undermine operation and/or performance of the optical device. Accordingly, there is a need in the art for layered polymeric structures that, among other things, protect optical devices from the environment in which they operate.

### SUMMARY

Various embodiments of the present invention relate to a layered polymeric structure, such as for use as an encapsulant in an optical assembly with respect to the optical surface of an optical device. The layered polymeric structure may include a first, a second layer, and a third layer, wherein the third layer is located between the first and second layers and the third layer is sometimes referred to herein as an “interlayer.” The first and second layers can comprise a silicone-containing hot melt composition (e.g., a resin-linear organosiloxane block copolymer composition comprising a resin-linear organosiloxane block copolymer), while the third layer can comprise an organosiloxane resin that is sufficiently compatible with the silicone-containing hot melt compositions that are present in the first and second layers, such that the third layer adheres the first and second layers. The layered polymeric structure may be a pre-formed encapsulant film comprising first, second, and third layers, wherein each of the first and second layers independently comprises a silicone-containing hot melt composition.

### FIGURES

FIG. 1 is a side profile of a layered polymeric structure, such as may be utilized as an encapsulant in an optical assembly.

FIG. 2 is a schematic of an optical assembly.

### DETAILED DESCRIPTION

The term “hot-melt,” as used herein, generally refers to a material that is solid at or below room temperature or at or below the use temperature and becomes a melt (e.g., a material that is characterized by a viscosity or can be otherwise deformed without completely reverting to its original dimensions at higher temperatures such as 80° C. to 150° C.).

“Hot-melt” compositions of the various examples and embodiments described herein may be reactive or unreactive. Reactive hot melt materials and compositions are chemically curable thermoset products which, after curing, are high in strength and resistant to flow (i.e., high viscosity) at room temperature. Non-limiting examples of reactive hot melt compositions include compositions containing alkenyl reactive groups including dimethylalkenylsiloxy-terminated dimethylpolysiloxanes; dimethylalkenylsiloxy-terminated copolymers of methylalkenylsiloxane and dimethylsiloxane; dimethylalkenylsiloxy-terminated copolymers of methylphenylsiloxane and dimethylsiloxane; dimethylalkenylsiloxy-terminated copolymers of methylphenylsiloxane, methylalkenylsiloxane, and dimethylsiloxane; dimethylalkenylsiloxy-terminated copolymers of diphenylsiloxane and dimethylsiloxane; dimethylalkenylsiloxy-terminated copolymers of diphenylsiloxane, methylalkenylsiloxane, and dimethylsiloxane; or any suitable combination of the foregoing. The viscosity of hot melt compositions tend to vary significantly with changes in temperature from being highly viscous at relatively low temperatures (e.g., at or below room temperature) to having comparatively low viscosities as temperatures increase towards a target temperature sufficiently higher than a working temperature, such as room temperature. In various examples, a target temperature is 200° C.

Reactive or non-reactive hot melt compositions are generally applied to a substrate at elevated temperatures (e.g., temperatures greater than room temperature, for example greater than 50° C.) as the composition is significantly less viscous at elevated temperatures (e.g., at temperatures from about 50 to 200° C.) than at approximately room temperature (e.g., at about 25° C.). In some cases, hot melt compositions are applied on to substrates at elevated temperatures as flowable masses and are then allowed to quickly “resolidify” merely by cooling. Other application methods include the application of sheets of hot melt material on, e.g., a substrate or superstrate, at room temperature, followed by heating.

In various examples, the layered polymeric structure includes a composition that is a solid (solid composition), e.g., at room temperature. In various other examples, the layered polymeric structure includes a composition having a refractive index greater than about 1.4.

In still other examples, the layered polymeric structure includes an organosiloxane block copolymer.

When the layered polymeric structure includes an organosiloxane block copolymer, the block copolymer comprises units of the formula [R¹₂SiO_{2/2}] and units of the formula [R²SiO_{3/2}] and has, in some examples, a weight average molecular weight of at least 20,000 g/mole. In some examples, the organosiloxane block copolymer may include 40 to 90 mole percent units of the formula [R¹₂SiO_{2/2}] arranged in linear blocks each having an average of from 10 to 400 units [R¹₂SiO_{2/2}] per linear block. In other examples, the organosiloxane block copolymer may also include 10 to 60 mole percent units of the formula [R²SiO_{3/2}] arranged in non-linear blocks each having a weight average molecular weight of at least 500 g/mol. In still other examples, the organosiloxane block copolymer may include 0.5 to 25 mole percent silanol groups. In these formulae, R¹ is independently a C₁ to C₃₀ hydrocarbyl (e.g., C₁ to C₃₀ hydrocarbon groups that can be, independently, alkyl, aryl, or alkylaryl groups). and R² is independently a C₁ to C₂₀ hydrocarbyl (e.g., C₁ to C₂₀ hydrocarbon groups that can be, independently, alkyl, aryl, or alkylaryl groups). In addition, in various examples, at least 30% of the non-linear blocks may be crosslinked with another non-linear block. In other various examples, the non-linear blocks may be aggregated in nano-domains. In still other examples, each linear block of the organosiloxane block copolymer may be linked to at least one non-linear block. The layered polymeric structure may have improved thickness control in comparison with various layered polymeric structures known in the art.

R¹ in units of the formula [R¹₂SiO_{2/2}] can be a C₁ to C₃₀ alkyl group (e.g., a C₁ to C₁₈ alkyl group, a C₁ to C₁₂ alkyl group, a C₁ to C₈ alkyl group, a C₁ to C₆ alkyl group or a C₁ to C₃ alkyl group). R¹ can be, for example, a C₁ to C₆ alkyl group such as methyl, ethyl, propyl, butyl, pentyl, or hexyl. Alternatively R¹ can be methyl. R¹ in units of the formula [R¹₂SiO_{2/2}] can be a C₆ to C₁₆ aryl group (e.g., a C₆ to C₁₄, C₆ to C₁₂ aryl group or a C₆ to C₁₀ aryl group). R¹ can be a C₆ to C₁₆ aryl group such as phenyl, naphthyl, or an anthryl group. Alternatively, R¹ can be any combination of the aforementioned alkyl or aryl groups. Alternatively, R¹ is phenyl, methyl, or a combination of both.

R² in units of the formula [R²SiO_{3/2}] can be a C₁ to C₃₀ alkyl group (e.g., a C₁ to C₁₈ alkyl group, a C₁ to C₁₂ alkyl group, a C₁ to C₈ alkyl group, a C₁ to C₆ alkyl group or a C₁ to C₃ alkyl group). R² can be, for example, a C₁ to C₆ alkyl group such as methyl, ethyl, propyl, butyl, pentyl, or hexyl. Alternatively R² can be methyl. R² in units of the formula [R²SiO_{3/2}] can be a C₆ to C₁₆ aryl group (e.g., a C₆ to C₁₄, C₆ to C₁₂ aryl group or a C₆ to C₁₀ aryl group). R² can be a C₆ to C₁₆ aryl group such as phenyl, naphthyl, or an anthryl group. Alternatively, R² can be any combination of the aforementioned alkyl or aryl groups. Alternatively, R² is phenyl, methyl, or a combination of both.

In various examples, the layered polymeric structure includes an interlayer (e.g., a layer comprising an organosiloxane resin) located between one or more layers of the layered polymeric structure (e.g., between the first layer and the second layer). The interlayer comprises any suitable material that serves to, among other things, adhere two or more layers of the layered polymeric structure. In some embodiments, the interlayer not only serves to adhere two or more layers of the layered polymeric structure, but also helps provide a smooth gradient in refractive index, e.g., when there is a refractive index gradient between the first layer and the second layer. The extent to which the interlayer adheres the two or more layers of the layered polymeric structure can be determined, in some embodiments, by how compatible the interlayer is with the two or more layers of the layered polymeric structure being adhered. Without wishing to be bound by theory, it is believed that the functional groups (e.g., the R¹ and R² described below) of the interlayer and the functional groups (e.g., the R¹ and R² described below) on the silicone-containing hot melt compositions that make up the first and second layers can influence the compatibility of the interlayer and the first and second layers, such that the third layer adheres the first and second layers.

The compatibility of the interlayer and the two or more layers of the layered polymeric structure can depend, in some embodiments, on the solubility parameters of the interlayer and the two or more layers of the layered polymeric structure. Briefly, solubility parameters are often used in industry to predict compatibility of polymers, chemical resistance, swelling of cured elastomers by solvents, permeation rates of solvents, and even to characterize the surfaces of pigments, fibers, and fillers. See, e.g., Miller-Chou, B. A. and Koenig, J. L., Prog. Polym. Sci. 28: 1223-1270 (2003) and Rameshwar Adhikari, Correlations Between Molecular Architecture, Morphology and Deformation Behaviour of Styrene/Butadiene Block Copolymers and Blends (Nov. 30, 2001) (unpublished Ph.D. dissertation, Martin Luther University Halle-Wittenberg), which are incorporated by reference as if fully set forth herein.

If two polymers are mixed, the most frequent result is a system that exhibits a complete phase separation due to the repulsive interaction between the components (i.e., the chemical incompatibility between the polymers). Complete miscibility in a mixture of two polymers requires that the following conditions be fulfilled.

ΔGₘ=ΔHₘ−TΔSₘ<0

where ΔGₘ, ΔHₘ, and TΔSₘ represent the Gibb's free energy, enthalpy, and entropy of mixing at temperature T, respectively. The lattice theory for the enthalpy of mixing in polymer solutions, developed by Flory and Huggins, can be formally applied to polymer mixtures, which provides an estimation of the miscibility of the polymers. The entropy and enthalpy of mixing of two polymers are given by the equations:

TΔSₘ=−k[n₁ ln φ₁+n₂ ln φ₂]

ΔHₘ=kTX₁₂Nφ₁φ₂

where φᵢ is the volume fraction of the polymer i and N=n₁+n₂ is the total number of polymer molecules in the mixture. The term X (xi) is called Flory-Huggins interaction parameter and can be further defined by the equation:

X₁₂=[V_{ref}(δ₁−δ₂)²]/RT

wherein V_{ref} is an appropriately chosen “reference volume,” sometimes taken as 100 cm³/mol; δ₁ and δ₂ are the solubility parameters of polymers 1 and 2; R is the gas constant (e.g., 8.3144621 Joules/mole·Kelvin); and T is the temperature (e.g., in Kelvin). The solubility parameters for any given polymer can be determined empirically. See, e.g., G. Ovejero et al., European Polymer Journal 43: 1444-1449 (2007), which is incorporated by reference as if fully set forth herein.

Hence, enthalpic and entropic contribution to free energy of mixing can be parameterized in terms of Flory-Huggins segmental interaction parameter X and the degree of polymerisation N, respectively. Since the entropic and enthalpic contribution to free energy density scale respectively as N⁻¹ and X, it is the product XN that dictates the block copolymer phase state, and it is called the reduced interaction parameter or lumped interaction parameter. In some embodiments, when the value of this parameter is less than or equal to 10 (e.g., less than 8, less than 6, less than 4, less than 2, less than 1; 0.5 to 10, from 1 to 3, from 2 to 9, from 3 to 8 or 5 to 10), the compatibility between the interlayer and the two or more layers of the layered polymeric structure being adhered is sufficient for adhesion between the interlayer and the two or more layers of the layered polymeric structure.

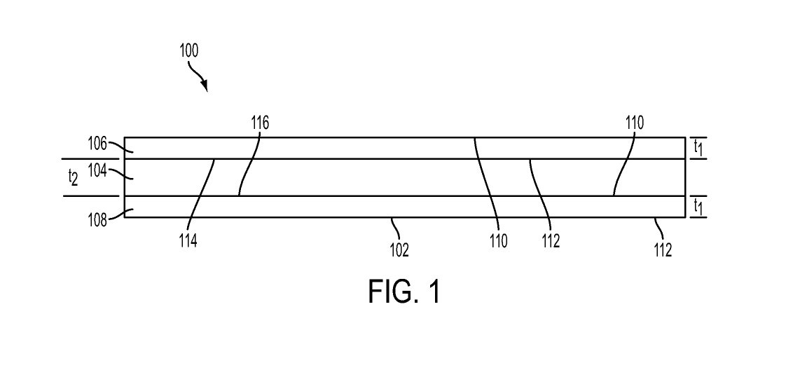

For example, in the context of block copolymers (e.g., organosiloxane block copolymers) AB and AC that could make up the first layer 106 and second layer 108, respectively, as shown in FIG. 1, materials are contemplated with regard to the third layer 104 where the first layer 106 and the third layer 104 have a first lumped interaction parameter, X₁N₁, with regard to an interaction between one of the blocks in the block copolymer making up the first layer 106 and the third layer 104, of less than 10. X₁ represents the Flory-Huggins interaction parameter for the interaction between one of the blocks in the block copolymer that makes up the first layer 106 and the third layer 104; and N₁ represents the degree of polymerization parameter, namely, the sum of the degree of polymerization of one of the blocks of the block copolymer that makes up the first layer 106 and the degree of polymerization of the third layer 104.

There is also a second lumped interaction parameter, X₂N₂, with regard to an interaction between one of the blocks in the block copolymer making up the second layer 108 and the third layer 104, of less than 10. X₂ represents the Flory-Huggins interaction parameter for the interaction between one of the blocks in the block copolymer that makes up the second layer 108 and the third layer 104; and N₂ represents the degree of polymerization parameter, namely, the sum of the degree of polymerization of one of the blocks of the block copolymer that makes up the second layer 108 and the degree of polymerization of the third layer 104.

In the non-limiting example where the first layer 106 comprises block copolymer AB and the second layer 108 comprises block copolymer AC, the third layer 104 could comprise an A homopolymer, such that the first lumped interaction parameter is less than 10 and the second lumped interaction parameter is less than 10.

With reference to FIG. 1, in another non-limiting example, the first layer 106 comprises a first resin-linear organosiloxane block copolymer comprising resin blocks comprising units of the formula [R¹₂SiO_{2/2}] and units of the formula [R²SiO_{3/2}] and linear blocks, the first layer 106 having a first major surface 110 and a second major surface 112; a second layer 108 comprising a second resin-linear organosiloxane block copolymer comprising resin blocks comprising units of the formula [R¹₂SiO_{2/2}] and units of the formula [R²SiO_{3/2}] and linear blocks, the second layer 108 having a first major surface 110 and a second major surface 112; and a third layer 104 comprising an organosiloxane resin comprising units of the formula [R¹₂SiO_{2/2}] and units of the formula [R²SiO_{3/2}], the third layer in direct contact with the second major surface 112 of the first layer and the first major surface 110 of the second layer; wherein R¹ is independently a C₁ to C₃₀ hydrocarbyl, and R² is independently a C₁ to C₂₀ hydrocarbyl. With further respect to FIG. 1, the first major surfaces 110 and the second major surfaces 112 of the layers 106, 108 are spaced apart by a thickness t₁; and the first major surface 114 and the second major surface 116 of the layer 104 is are spaced apart by a thickness t₂.

In some embodiments, about 20 to about 100 mole percent of at least one of the R¹ groups of the units of the formula [R¹₂SiO_{2/2}] and R² groups of the units of the formula [R²SiO_{3/2}] of the resin blocks of at least one of the first resin-linear organosiloxane block copolymer of the first layer and the second resin-linear organosiloxane block copolymer of the second layer are C₆-C₁₆ aryl groups; and about 20 to about 100 mole percent of at least one of the R¹ groups of the units of the formula [R¹₂SiO_{2/2}] and R² groups of the units of the formula [R²SiO_{3/2}] of the organosiloxane resin of the third layer are C₆-C₁₆ aryl groups. In other embodiments, about 20 to about 100 mole percent of at least one of the R¹ groups of the units of the formula [R¹₂SiO_{2/2}] and R² groups of the units of the formula [R²SiO_{3/2}] of the resin blocks of at least one of the first resin-linear organosiloxane block copolymer of the first layer and the second resin-linear organosiloxane block copolymer of the second layer are C₁-C₆ alkyl groups; and about 20 to about 100 mole percent of at least one of the R¹ groups of the units of the formula [R¹₂SiO_{2/2}] and R² groups of the units of the formula [R²SiO_{3/2}] of the organosiloxane resin of the third layer are C₁-C₆ alkyl groups.

In some examples, the first and second layers 106, 108 include a Ph-T-PhMe resin-linear block copolymer and a Ph-T-PDMS resin-linear block copolymer, respectively. In this case, the third layer 104 can include a Ph-T resin as the homopolymer that is common between the Ph-T blocks in the resin linear block copolymers that make up first and second layers 106, 108. In this example, the third layer comprises an organosiloxane resin (Ph-T resin) that is common with the resin blocks (Ph-T blocks) of at least one of the first resin-linear organosiloxane block copolymer and the second resin-linear organosiloxane block copolymer.

FIG. 1 is a side profile of a layered polymeric structure 100, such as may be utilized as an encapsulant in an optical assembly, such as the ones described herein. The thickness of the layers in the polymeric structure 100 shown in FIG. 1 are not meant to be to scale, such that, e.g., the third layer 104 is thicker than the first and second layers 106, 108. Indeed, the third layer 104 can be thinner (e.g., significantly thinner) than the first and second layers 106, 108. In some embodiments, the first layer 106 is in direct contact with an optical surface of an optical device. In other embodiments, the second layer 108 is in direct contact with an optical surface of an optical device.

In various embodiments, the layered polymeric structures include pre-formed encapsulant films. As used herein, the term “pre-formed encapsulant film” refers broadly to layered polymeric structures that are formed before they are used to cover an optical surface of an optical device, e.g., before they are, e.g., disposed on an optical surface of an optical device. Pre-formed encapsulant films can take any suitable form including the form of sheets of any suitable dimension or a tape of any suitable width and length. For example before it is used to cover the optical surface of the optical device, the pre-formed encapsulant film may be a free-standing film, sheet or tape. The term “pre-formed encapsulant film,” however, does not include the forming of a layer of a layered polymeric structure on, e.g., the optical surface of an optical device, followed by the forming of another layer of a layered polymeric structure on top, and so on.

In some embodiments, the pre-formed encapsulant film is pre-formed by forming the first layer; forming the second layer; applying an organosiloxane resin composition (i.e., forming the third layer) to at least one of the second major surface of the first layer and the first major surface of the second layer; contacting the second major surface of the first layer and the first major surface of the second layer to which the organosiloxane resin has been applied to form a layered polymeric structure; and laminating the layered polymeric structure as described herein (e.g., vacuum laminating).

The layered polymeric structure 100 includes a body 102 that may include a silicone-containing hot-melt composition, such as is described in detail herein. The body 102 may incorporate multiple layers of silicone-containing hot melt composition. The body 102 may include phosphors and may be formed so as to create a gradient (e.g., a gradient across each individual layer of a layered polymeric structure) of various characteristics. The phosphor, when present, can be present in a density gradient and the optical assembly includes a controlled dispersion of the phosphor. In this example, the controlled dispersion may be sedimented and/or precipitated.

In various examples, the layered polymeric structure 100 is between about 50 μm and 5000 μm thick. In some examples, the first layer 106 can be 50 to about 2500 microns (e.g., from about 50 to about 100 microns, from about 50 to about 500 microns; from about 60 to about 250 microns; from about 750 to about 1000 microns, or from about 1000 to about 2500 microns) thick. In some examples, the second layer 108 can be 50 to about 2500 microns (e.g., from about 50 to about 100 microns, from about 50 to about 500 microns; from about 60 to about 250 microns; from about 750 to about 1000 microns, or from about 1000 to about 2500 microns) thick. In still other examples, the third layer 104, which is sometimes referred to herein as an “interlayer,” can be 0.1 to about 1000 microns (e.g., from about 0.1 to about 100 microns, from about 0.5 to about 500 microns; from about 0.5 to about 50 microns; from about 0.5 to about 20 microns; or from about 0.1 to about 1 micron thick.

In various examples, the body 102 and one or more layers that may make up the body may include at least one of a resin-linear composition, a hydrosilylation cure composition, a high-phenyl-T composition, a silicon sealant composition, a polyurea-polysiloxane composition, an MQ/polysiloxane composition, an MQ/X-diorganosiloxane composition, a polyimide-polysiloxane composition, a polycarbonate-polysiloxane composition, a polyurethane-polysiloxane composition, a polyacrylate-polysiloxane composition or a polyisobutylene-polysiloxane composition. In some embodiments, polycarbonate and polycarbonate-siloxane copolymer mixtures are contemplated.

With respect to FIG. 1, in various examples, the first layer 106 and the second layer 108 are both silicone-containing hot melt compositions, but which, in various examples, can include different chemistries. As will be disclosed in detail herein, such different chemistries may be relatively minor between layers 106, 108 or may incorporate significant differences. In various examples disclosed herein, the first layer has material properties, such as a modulus, a hardness, a refractive index, a light transmittance or a thermal conductivity that are different from that of the second layer. In various examples, the third layer 104 functions as an adhesive layer that adheres, at least in part, layers 106, 108 in the layered polymeric structure 100.

With further respect to FIG. 1, in some examples one or more of the major surfaces of any given layer can be rough or roughened, in whole or in part. For example, the first major surface 110 of the first layer 106 may be rough or roughened, in whole or in part, or may substantially repel dust, such as dust that may come from the environment (outdoor or indoor) or from within an optical assembly (e.g., photovoltaic panels and other optical energy-generating devices, optocouplers, optical networks and data transmission, instrument panels and switches, courtesy lighting, turn and stop signals, household appliances, VCR/DVD/stereo/audio/video devices, toys/games instrumentation, security equipment, switches, architectural lighting, signage (channel letters), machine vision, retail displays, emergency lighting, neon and bulb replacement, flashlights, accent lighting full color video, monochrome message boards, in traffic, rail, and aviation applications, in mobile phones, personal digital assistants (PDAs), digital cameras, lap tops, in medical instrumentation, bar code readers, color & money sensors, encoders, optical switches, fiber optic communication, and combinations thereof).

With further respect to FIG. 1, the layers 104, 106, 108 can be secured with respect to one another through various processes disclosed herein, including lamination. The first and second layers may be individually cured or not cured as appropriate to the particular compositions used therein. In an example, only one of the layers 106, 108 is cured, while the other one of the layers 106, 108 may set without curing. In an example, each of the first and second layers 106, 108 are cured, but cure at different cure speeds. In various examples, each of the first and second layers 106, 108 have the same or different curing mechanisms. In an example, at least one of the curing mechanisms of the layers 106, 108 include a hot melt cure, moisture cure, a hydrosilylation cure (as described herein), a condensation cure, peroxide/radical cure, photo cure or a click chemistry-based cure that involves, in some examples, metal-catalyzed (copper or ruthenium) reactions between an azide and an alkyne or a radical-mediated thiol-ene reactions.

With further respect to FIG. 1, the curing mechanisms of the layers 106,108 may include combinations of one or more cure mechanisms within the same layer 106 or 108 or in each layer 106 or 108. For example, the curing mechanism within the same layer 106 or 108 may include a combination of a hydrosilylation and a condensation cure, where the hydrosilylation occurs first and is followed by the condensation cure as described herein or vice versa (e.g., hydrosilylation/alkoxy or alkoxy/hydrosilylation); a combination of a ultra-violet photo cure and a condensation cure (e.g., UV/alkoxy); a combination of a silanol and an alkoxy cure; a combination of a silanol and hydrosilylation cure; or a combination of an amide and a hydrosilylation cure. The third layer can be cured or uncured. In some embodiments, the third layer is uncured, but, like the first layer and the second layer, can be cured after the layered polymeric structure is prepared.

With further respect to FIG. 1, in some examples, the first and second layers 106, 108 include Ph-T-PhMe in one layer and Ph-T-PhMe in the other layer. In some examples, one of the Ph-T-PhMe layers is a high refractive index Ph-T-PhMe layer. As used herein, the term “high refractive index” refers to refractive indices of from about 1.5 to about 1.6, e.g., from about 1.55 to about 1.58 or from about 1.56 to about 1.58. In other examples, one of the Ph-T-PhMe layers is cured. In some examples, one of the Ph-T-PhMe layers has a thickness of from about 50 to about 100 microns (e.g., from about 50 to about 75 microns; from about 60 to about 90 microns; or from about 75 to about 100 microns). In other examples, one of the Ph-T-PhMe layers has a thickness of from about 0.3 to about 1.5 mm (e.g., from about 0.5 to about 1.3 mm; from about 1 to about 1.5 mm; or from about 0.75 to about 1.5 mm). In still other examples, In yet other examples, one of the Ph-T-PhMe includes a phosphor.

With further respect to FIG. 1, in some examples, the first and second layers 106, 108 can generally have the same thickness. In some examples, the first and second layers 106, 108 include Ph-T-PhMe in one layer and Ph-T-PDMS in the other layer. In some examples, the Ph-T-PhMe layer is a high refractive index Ph-T-PhMe layer. In some examples, the Ph-T-PhMe layer has a thickness of from about 50 to about 100 microns (e.g., from about 50 to about 75 microns; from about 60 to about 90 microns; or from about 75 to about 100 microns). In other examples, the Ph-T-PDMS layer has a thickness of from about 0.3 to about 1.5 mm (e.g., from about 0.5 to about 1.3 mm; from about 1 to about 1.5 mm; or from about 0.75 to about 1.5 mm). In yet other examples, the Ph-T-PhMe layer includes a phosphor. In some embodiments, the first and second layers 106, 108 can generally have the same thickness.

With further respect to FIG. 1, in some examples, the first and second layers 106, 108 include Ph-T-PhMe in one layer and MQ/-PDMS in the other layer. In some examples, the Ph-T-PhMe layer is a high refractive index Ph-T-PhMe layer. In some examples, the Ph-T-PhMe layer has a thickness of from about 50 to about 100 microns (e.g., from about 50 to about 75 microns; from about 60 to about 90 microns; or from about 75 to about 100 microns). In other examples, the MQ/PDMS layer has a thickness of from about 0.3 to about 1.5 mm (e.g., from about 0.5 to about 1.3 mm; from about 1 to about 1.5 mm; or from about 0.75 to about 1.5 mm). In yet other examples, the Ph-T-PhMe layer includes a phosphor.

With further respect to FIG. 1, in some examples, the first and second layers 106, 108 include Ph-T-PhMe in one layer and Np-T-PhMe in the other layer. In some examples, the Ph-T-PhMe layer is a high refractive index Ph-T-PhMe layer. In some examples, the Np-T-PhMe layer is an ultra-high refractive index Np-T-PhMe layer. As used herein, the term “ultra-high refractive index” refers to refractive indices greater than 1.58, e.g., greater than 1.65, greater than 1.75; from about 1.6 to about 2.5; from about 1.75 to about 2; or from about 1.65 to about 2. In other examples, the Ph-T-PhMe layer has a thickness of from about 0.3 to about 1.5 mm (e.g., from about 0.5 to about 1.3 mm; from about 1 to about 1.5 mm; or from about 0.75 to about 1.5 mm). In other examples, the Np-T-PhMe layer has a thickness of from about 50 to about 100 microns (e.g., from about 50 to about 75 microns; from about 60 to about 90 microns; or from about 75 to about 100 microns). In yet other examples, the Np-T-PhMe layer includes a phosphor.

With further respect to FIG. 1, in some examples, the third layer 104 includes an organosiloxane resin. The organosiloxane resin may comprise at least 60 mol % of [R²SiO_{3/2}] siloxy units in its formula (e.g., at least 70 mol % of [R²SiO_{3/2}] siloxy units, at least 80 mole % of [R²SiO_{3/2}] siloxy units, at least 90 mole % of [R²SiO_{3/2}] siloxy units, or 100 mole % of [R²SiO_{3/2}] siloxy units; or 60-100 mole % [R²SiO_{3/2}] siloxy units, 60-90 mole % [R²SiO_{3/2}] siloxy units or 70-80 mole % [R²SiO_{3/2}] siloxy units), where each R² is independently a C₁ to C₂₀ hydrocarbyl, as the term is defined herein. Alternatively, the organosiloxane resin is a silsesquioxane resin, or alternatively a phenyl silsesquioxane resin. Commercially-available organosiloxane resins that can make up the third layer 104 include, but are not limited to XIAMETER® brand resins, including, but not limited to, RSN-0409 HS resin, RSN-0233 resin, RSN-0249 resin, RSN-0255 resin, RSN-0255 resin, and RSN-0217 resin, all of which are available from Dow Corning, Midland, Mich.

With further respect to FIG. 1, the first layer and/or the second layer 108 is or includes a phosphor within a silicone-containing hot melt composition.

The phosphor contemplated for use in the various embodiments described herein can be any suitable phosphor. In an example, the phosphor is made from a host material and an activator, such as copper-activated zinc sulfide and silver-activated zinc sulfide. The host material may be selected from a variety of suitable materials, such as oxides, nitrides and oxynitrides, sulfides, selenides, halides or silicates of zinc, cadmium, manganese, aluminum, silicon, or various rare earth metals, Zn₂SiO₄:Mn (Willemite); ZnS:Ag+(Zn,Cd)S:Ag; ZnS:Ag+ZnS:Cu+Y₂O₂S:Eu; ZnO:Zn; KCl; ZnS:Ag,Cl or ZnS:Zn; (KF,MgF₂):Mn; (Zn,Cd)S:Ag or (Zn,Cd)S:Cu; Y₂O₂S:Eu+Fe₂O₃, ZnS:Cu,Al; ZnS:Ag+Co-on-Al₂O₃; (KF,MgF2):Mn; (Zn,Cd)S:Cu,Cl; ZnS:Cu or ZnS:Cu,Ag; MgF₂:Mn; (Zn,Mg)F₂:Mn; Zn₂SiO₄:Mn,As; ZnS:Ag+(Zn,Cd)S:Cu; Gd₂O₂S:Tb; Y₂O₂S:Tb; Y₃Al₅O₁₂:Ce; Y₂SiO₅:Ce; Y₃Al₅O₁₂:Tb; ZnS:Ag,Al; ZnS:Ag; ZnS:Cu,Al or ZnS:Cu,Au,Al; (Zn,Cd)S:Cu,Cl+(Zn,Cd)S:Ag,Cl; Y₂SiO₅:Tb; Y₂OS:Tb; Y₃(Al,Ga)₅O₁₂:Ce; Y₃(Al,Ga)₅O₁₂:Tb; InBO₃:Tb; InBO₃:Eu; InBO₃:Tb+InBO₃:Eu; In BO₃:Tb+In BO₃:Eu+ZnS:Ag; (Ba,Eu)Mg₂Al₁₆O₂₇; (Ce,Tb)MgAl₁₁O₁₉; BaMg Al₁₀O₁₇:Eu,Mn; BaMg₂Al₁₆O₂₇:Eu(II); BaMgAl₁₀O₁₇:Eu,Mn; BaMg₂Al₁₆O₂₇:Eu(II),Mn(II); Ce_{0.67}Tb_{0.33}MgAl₁₁O₁₉:Ce,Tb; Zn₂SiO₄:Mn,Sb₂O₃; CaSiO₃:Pb,Mn; CaWO₄ (Scheelite); CaWO₄:Pb; MgWO₄; (Sr,Eu,Ba,Ca)₅(PO₄)₃Cl; Sr₅Cl(PO₄)₃:Eu(II); (Ca,Sr,Ba)₃(PO₄)₂Cl₂:Eu; (Sr,Ca,Ba)₁₀(PO₄)₆C₁₂:Eu; Sr₂P₂O₇:Sn(II); Sr₆P₅BO₂₀:Eu; Ca₅F(PO₄)₃:Sb; (Ba,Ti)₂P₂O₇:Ti; 3Sr₃(PO₄)₂.SrF₂:Sb,Mn; Sr₅F(PO₄)₃:Sb,Mn; Sr₅F(PO₄)₃:Sb,Mn; LaPO₄:Ce,Tb; (La,Ce,Tb)PO₄; (La,Ce,Tb)PO₄:Ce,Tb; Ca₃(PO₄)₂CaF₂:Ce,Mn; (Ca,Zn,Mg)₃(PO₄)₂:Sn; (Zn,Sr)₃(PO₄)₂:Mn; (Sr,Mg)₃(PO₄)₂:Sn; (Sr,Mg)₃(PO₄)₂:Sn(II); Ca₅F(PO₄)₃:Sb,Mn; Ca₅(F,Cl)(PO₄)₃:Sb,Mn; (Y,Eu)₂O₃; Y₂O₃:Eu(III); Mg₄(F)GeO₆:Mn; Mg₄(F)(Ge,Sn)O₆:Mn; Y(P,V)O₄:Eu; YVO₄:Eu; Y₂O₂S:Eu; 3.5 MgO.0.5 MgF₂.GeO₂:Mn; Mg₅As₂O₁₁:Mn; SrAl₂O₇:Pb; LaMgAl₁O₁₉:Ce; LaPO₄:Ce; SrAl₁₂O₁₉:Ce; BaSi₂O₅:Pb; SrFB₂O₃:Eu(II); SrB₄O₇:Eu; Sr₂MgSi₂O₇:Pb; MgGa₂O₄:Mn(II); Gd₂O₂S:Tb; Gd₂O₂S:Eu; Gd₂O₂S:Pr; Gd₂O₂S:Pr,Ce,F; Y₂O₂S:Tb; Y₂O₂S:Eu; Y₂O₂S:Pr; Zn(0.5)Cd(0.4)S:Ag; Zn(0.4)Cd(0.6)S:Ag; CdWO₄; CaWO₄; MgWO₄; Y₂SiO₅:Ce; YAlO₃:Ce; Y₃Al₅O₁₂:Ce; Y₃(Al,Ga)₅O₁₂:Ce; CdS:In; ZnO:Ga; ZnO:Zn; (Zn,Cd)S:Cu,Al; ZnS:Cu,Al,Au; ZnCdS:Ag,Cu; ZnS:Ag; anthracene, EJ-212, Zn2SiO4:Mn; ZnS:Cu; Nal:Tl; Csl:Tl; LiF/ZnS:Ag; LiF/ZnSCu,Al,Au, and combinations thereof.

With further respect to FIG. 1, in various examples, the phosphor may be dispersed in the first layer 106 and/or the second layer 108. Additionally or alternatively, the phosphor may be dispersed in a discrete layer, e.g., the phosphor may be present in a layer independent from a solid composition or may be combined with another composition, such as the silicone-containing hot melt composition.

With further respect to FIG. 1, the one or more layers 106, 108 may include a gradient (e.g., a gradient of a modulus and/or of hardness in any one or more layers). In an example, the gradient may be of the silicone-containing hot melt composition and/or of a phosphor. The gradient may be continuous (e.g., uninterrupted and/or consistently changing) or stepped, e.g., discontinuous or changing in one or more steps. In various examples, the stepped gradient can reflect different layers between steps. The term “gradient” may describe a graded change in the amount of components of, for instance, the silicone-containing hot melt composition and/or the amounts of the phosphor. The gradient may also describe a graded change in the magnitude of the light produced by the phosphor.

With further respect to FIG. 1, in one example, the gradient may be further defined as a vector field which points in the direction of the greatest rate of increase and whose magnitude is the greatest rate of change. In another example, the gradient may be further defined as a series of two-dimensional vectors at points on the silicone-containing hot melt composition and/or phosphor with components given by the derivatives in horizontal and vertical directions. In an example, at each point the vector points in the direction of a largest increase, and the length of the vector corresponds to the rate of change in that direction.

With further respect to FIG. 1, in an example, the composition comprises a gradient of units of the formula [R¹₂SiO_{2/2}] and units of the formula [R²SiO_{3/2}]. In another example, the composition includes a gradient of units of the formula [R¹₂SiO_{2/2}], units of the formula [R²SiO_{3/2}], and silanol groups. In still another example, the composition includes a gradient of units of the formula [R²SiO_{3/2}] and silanol groups. In a further example, the composition includes a gradient of units of the formula [R¹₂SiO_{2/2}] and silanol groups. In addition, silicone compositions ranging in refractive index can be used to prepare a composition gradient. For example, a phenyl-T-PDMS resin-linear with refractive index of 1.43 can be combined with a phenyl-T-PhMe resin-linear with a refractive index of 1.56 to create a gradient. Such an example may provide a relatively smooth transition from a high refractive index optical device, such as an LED, to an air surface.

With further respect to FIG. 1, in the illustrated example, the gradient creates a relatively harder composition proximate third layer 104 and a relatively softer composition distal of the third layer 104. Such an example of a layered polymeric structure 100 may, in various examples, be utilized, for instance, to present a relatively soft surface to an optical surface of an optical device that includes relatively sensitive electronic components, such as an LED. At the same time, the relatively hard surface of the layer 106, 108 that forms a gradient may be exposed to environmental conditions may provide useful resiliency for the resultant optical assembly. In various alternative examples, the side of the layered polymeric structure 100 that is exposed to environmental conditions may advantageously be relatively softer than the internal conditions, dependent on the particular circumstances of its use. In an example, the first layer 106 includes a phosphor and the second layer 108 includes the composition that has a gradient.

With further respect to FIG. 1, in some examples the first layer 106 includes a first phosphor to make the first layer 106 modify light passing therethrough according to a wavelength corresponding to a first color. The second layer 108 includes a second phosphor to make the second layer 108 modify light passing therethrough according to a wavelength corresponding to a second color. In an example, the first and second colors are yellow and red, respectively, though in various examples the colors are selectable based on the characteristics of the optical device with which the layered polymeric structure 100 is to be associated. The third layer 104 can be selected to not purposefully distort light. As noted above, the ordering of the layers 104, 106, 108 may be selected dependent on the characteristics of an associated optical device. In an example, the layered polymeric structure 100 can comprise a fourth layer (not shown; e.g., a tie layer, as described herein) configured to be placed on an optical surface of the optical device and may include an adhesive to adhere, at least in part, the layered polymeric structure 100 with respect to the optical device and the optical surface.

With further respect to FIG. 1, various alternative examples of layered polymeric structures 100 are contemplated, including certain combinations of layers utilized therein. In an example, the layered polymeric structure 100 includes one layer 106 with a phosphor and one clear layer 108.

The optical assemblies disclosed herein may have various architectures. For example, the optical assembly may include only an optical device and a layered polymeric structure acting as an encapsulant with a body (e.g., the body 102 of FIG. 1). Alternatively, the optical assembly may include only an optical device and a layered polymeric structure acting as an encapsulant with a body (e.g., the body 102 of FIG. 1) and may further include a release liner (not shown) disposed on or with respect to the encapsulant and/or the optical device. The release liner may include a release agent for the promotion of securing the layered polymeric structure 100 to another object, such as an optical device. In various examples, the release liner is or includes siliconized PET or a fluorinated liner. In various examples, the release liner is smooth or is textured, such as to act as an anti-reflective surface.

The optical assembly may be in various known applications, such as in photovoltaic panels and other optical energy-generating devices, optocouplers, optical networks and data transmission, instrument panels and switches, courtesy lighting, turn and stop signals, household appliances, VCR/DVD/stereo/audio/video devices, toys/games instrumentation, security equipment, switches, architectural lighting, signage (channel letters), machine vision, retail displays, emergency lighting, neon and bulb replacement, flashlights, accent lighting full color video, monochrome message boards, in traffic, rail, and aviation applications, in mobile phones, personal digital assistants (PDAs), digital cameras, lap tops, in medical instrumentation, bar code readers, color & money sensors, encoders, optical switches, fiber optic communication, and combinations thereof.

The optical devices can include at least one coherent light source, such as various lasers known in the art, as well as incoherent light sources, such as light emitting diodes (LED) and various types of light emitting diodes, including semiconductor LEDs, organic LEDs, polymer LEDs, quantum dot LEDs, infrared LEDs, visible light LEDs (including colored and white light), ultraviolet LEDs, and combinations thereof.

The optical assembly may also include one or more layers or components known in the art as typically associated with optical assemblies. For example, the optical assembly may include one or more drivers, light guides, optics, heat sinks, housings, lenses, power supplies, fixtures, wires, electrodes, circuits, and the like.

The optical assembly may also include a substrate and/or a superstrate. The substrate and the superstrate may be the same or may be different and each may independently include any suitable material known in the art. The substrate and/or superstrate may be soft, flexible, rigid, or stiff. Alternatively, the substrate and/or superstrate may include rigid and stiff segments while simultaneously including soft and flexible segments. The substrate and/or superstrate may be transparent to light, may be opaque, or may not transmit light (i.e., may be impervious to light). A superstrate may transmit light. In one example, the substrate and/or superstrate includes glass. In another example, the substrate and/or superstrate includes metal foils, polyimides, ethylene-vinyl acetate copolymers, and/or organic fluoropolymers including, but not limited to, ethylene tetrafluoroethylene (ETFE), TEDLAR® (DuPont, Wilmington, Del.), polyester/TEDLAR®, TEDLAW/polyester/TEDLAR®, polyethylene terephthalate (PET) alone or coated with silicon and oxygenated materials (SiOx), and combinations thereof. In one example, the substrate is further defined as a PET/SiOx-PET/Al substrate, wherein x has a value of from 1 to 4.

The substrate and/or superstrate may be load bearing or non-load bearing and may be included in any portion of the optical assembly. The substrate may be a “bottom layer” of the optical assembly that is positioned behind the optical device and serves, at least in part, as mechanical support for the optical device and the optical assembly in general. Alternatively, the optical assembly may include a second or additional substrate and/or superstrate. The substrate may be the bottom layer of the optical assembly while a second substrate may be the top layer and function as the superstrate. A second substrate (e.g., a second substrate functioning as a superstrate) may be substantially transparent to light (e.g., visible, UV, and/or infrared light) and is positioned on top of the substrate.

In addition, the optical assembly may also include one or more tie layers. The one or more tie layers may be disposed on the substrate to adhere the optical device to the substrate. In one example, the optical assembly does not include a substrate and does not include a tie layer. The tie layer may be transparent to UV, infrared, and/or visible light. However, the tie layer may be impermeable to light or opaque. The tie layer may be tacky and may be a gel, gum, liquid, paste, resin, or solid. In one example, the tie layer is a film.

In some examples, the optical assembly may include one or more gas barrier layers present in any portion of the optical assembly. The optical assembly may include one or more of a tackless layer, a non-dust layer, and/or a stain layer present in any portion of the optical assembly. The optical assembly may further include a combination of a B-stage film (e.g., an embodiment of the pre-formed encapsulant film) and include one or more layers of a non-melting film. The optical assembly may also include one or more hard layers, e.g., glass, polycarbonate, or polyethylene terephthalate, disposed within, e.g., on top, of the optical assembly. The hard layer may be disposed as an outermost layer of the optical assembly. The optical assembly may include a first hard layer as a first outermost layer and a second hard layer as a second outermost layer. The optical assembly may further include one or more diffuser infused layers disposed in any portion of the optical assembly. The one or more diffuser layers may include, for example, e-powder, TiO₂, Al₂O₃, etc. The optical assembly may include a reflector and/or the solid composition (e.g., as a film) may include reflector walls embedded therein. Any one or more of the layers of the solid state film may be smooth, may be patterned, or may include smooth portions and patterned portions. The optical assembly may alternatively include, for example instead of a phosphor, carbon nanotubes. Alternatively, carbon nano-tubes may be aligned in a certain direction, for example on a wafer surface. A film can be cast around these carbon nanotubes to generate a transparent film with improved heat dissipation character.

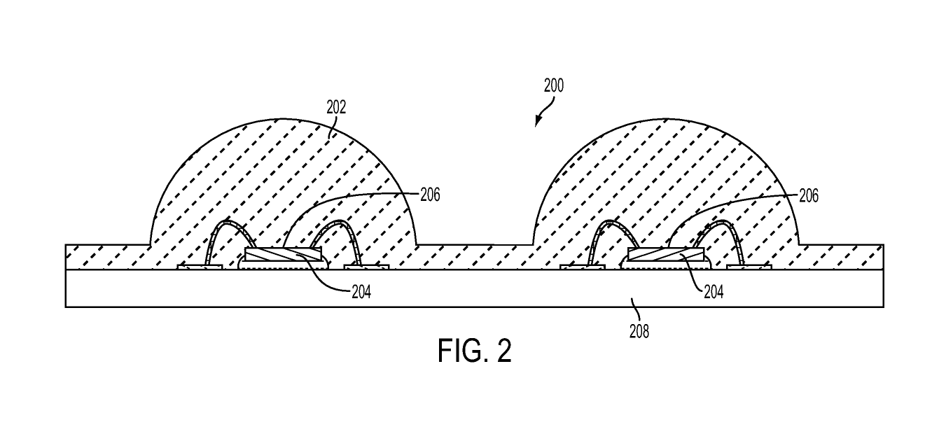

FIG. 2 is an image an example of an optical assembly 200. The optical assembly includes an encapsulant 202, optical devices 204 each having an optical surface 206 and each positioned on a substrate 208. A silicone composition of the encapsulant 202 may be heated at 100° C. for 30 minutes by hot-press with a 1 mm depth mold. A 1 mm thickness B-stage transparent sheet or layer may be incorporated. The encapsulant 202 may be compression molded to the optical devices 204, as illustrated in a mold with dome-shape cavities. A transparent sheet or layer may be incorporated in the encapsulant 202. The encapsulant 202 as incorporated into the optical assembly 200 may be obtained by compression molding at 130° C. for five (5) minutes to melt the encapsulant 202 and cure the encapsulant 202 in the dome-shape cavities.

With further respect to FIG. 2, the encapsulant 202 may be or may include a body with multiple layers as disclosed herein, such as the body 102 (FIG. 1). While various examples of optical assemblies are disclosed herein, the encapsulant 202 of the optical assembly 200 may be configured according to any of various combinations of layers of materials disclosed herein. Further, the optical device 204 may be any of the optical devices 204 disclosed herein or known in the art. As with other encapsulants disclosed herein, the encapsulant 202 substantially or entirely covers the optical surface 206 of the optical device 202.

The optical assemblies of the embodiments described herein include, among other things, an encapsulant. The encapsulant, in turn, includes a first layer comprising a first reactive or non-reactive silicone-containing hot melt composition; and a second layer comprising a second reactive or non-reactive silicone-containing hot melt composition. The first and/or second silicone-containing composition includes at least one of a resin-linear composition, a hydrosilylation cure composition, a high-phenyl-T composition, a silicon sealant composition, a polyurea-polysiloxane composition, an MQ/polysiloxane composition, an MQ/X-diorganosiloxane composition, a polyimide-polysiloxane composition, a polycarbonate-polysiloxane composition, a polyurethane-polysiloxane composition a polyacrylate-polysiloxane composition or a polyisobutylene-polysiloxane composition. In some embodiments, polycarbonate and polycarbonate-siloxane copolymer mixtures are contemplated. In other embodiments, compositions are contemplated where resin-linear organosiloxane block copolymer compositions, such as those described herein and those described in Published U.S. Appl. Nos. 2013/0168727 and 2013/0245187 (the entireties of both of which are incorporated by reference as if fully set forth herein) are combined with linear or resin organopolysiloxane components by, e.g., blending methods. Such compositions are described in U.S. Provisional Patent Appl. Ser. No. 61/613,510, filed Mar. 21, 2012. Such compositions exhibit improved toughness and flow behavior of the resin-linear organosiloxane block copolymer compositions with minimum impact, if any, on the optical transmission properties of cured films of resin-linear organosiloxane block copolymers.

As used herein, the term “resin-linear composition” and “resin-linear organosiloxane block copolymer composition” (both terms can be used interchangeably herein) includes a resin-linear organosiloxane block copolymer having an organosiloxane “resin” portion coupled to an organosiloxane “linear” portion. Resin-linear compositions are described in greater detail below. Resin-linear compositions also include those disclosed in U.S. Pat. No. 8,178,642, the entirety of which is incorporated by reference as if fully set forth herein. Briefly, the resin-linear compositions disclosed in the '642 patent include compositions containing: (A) a solvent-soluble organopolysiloxane resulting from the hydrosilylation reaction between an organopolysiloxane represented by the average structural formula RₐSiO_{(4-a)/2} and a diorganopolysiloxane represented by the general formula HR²₂Si(R²₂SiO)ₙR²₂SiH; and (B) an organohydrogenpolysiloxane represented by the average structural formula R²_{b}H_{c}SiO; and (C) a hydrosilylation catalyst, where the variables Rₐ, R², a, n, b, and c are defined therein.

As disclosed in detail herein, the resin-linear composition may include various characteristics. In certain resin-linear compositions, the composition includes a resin-rich phase and a phase separated linear-rich phase.

As used herein, the term “high-phenyl-T compositions” includes compositions obtained by crosslinking a phenyl group-containing organopolysiloxane represented by the average units formula:

(R³₃SiO_{1/2})ₐ(R³₂SiO_{2/2})_{b}(R³SiO_{3/2})_{c}(SiO_{4/2})_{d}(R⁴O_{1/2})ₑ

wherein R³ is a phenyl group, alkyl or cycloalkyl group having 1 to 6 carbon atoms, or an alkenyl group having 2 to 6 carbon atoms, with the proviso that 60 to 80 mole % of R³ are phenyl groups and 10 to 20 mole % of R³ are alkenyl groups; R⁴ is a hydrogen atom or an alky group having 1 to 6 carbon atoms; “a,” “b,” “c,” “d,” and “e” are numbers that are satisfied by the following conditions: 0≦a≦0.2, 0.2≦b≦0.7, 0.2≦c≦0.6, 0≦d≦0.2, 0≦e≦0.1, and a+b+c+d=1.

The term “high-phenyl-T compositions” also includes compositions obtained by partially crosslinking a silicone composition including:

(A) a phenyl group-containing organopolysiloxane represented by the following average units formula:

(R³₃SiO_{1/2})ₐ(R³₂SiO_{2/2})_{b}(R³SiO_{3/2})_{c}(SiO_{4/2})_{d}(R⁴O_{1/2})ₑ

wherein R³ is a phenyl group, alkyl or cycloalkyl group having 1 to 6 carbon atoms, or an alkenyl group having 2 to 6 carbon atoms, with the proviso that 60 to 80 mole % of R³ are phenyl groups and 10 to 20 mole % of R³ are alkenyl groups; R⁴ is a hydrogen atom or an alky group having 1 to 6 carbon atoms; “a,” “b,” “c,” “d,” and “e” are numbers that are satisfied by the following conditions: 0≦a≦0.2, 0.2≦b≦0.7, 0.2≦c≦0.6, 0≦d≦0.2, 0≦e≦0.1, and a+b+c+d=1;

(B) a phenyl group-containing organopolysiloxane represented by the following general formula:

R⁵₃SiO(R⁵₂SiO)ₘSiR⁵₃

wherein R⁵ is a phenyl group, alkyl or cycloalkyl group having 1 to 6 carbon atoms, or an alkenyl group having 2 to 6 carbon atoms, with the proviso that 40 to 70 mole % of R⁵ are phenyl groups and at least one of R⁵ is a alkenyl group; “m” is an integer of 5 to 100;

(C) a phenyl group-containing organopolysiloxane having at least two silicon atom-bonded hydrogen atoms per molecule; and

(D) a hydrosilylation reaction catalyst.

In some examples, component (C) is an organotrisiloxane represented by the general formula: (HR⁶₂SiO)₂Si R⁶₂

wherein R⁶ is a phenyl group, or alkyl or cycloalkyl group having 1 to 6 carbon atoms, with the proviso that 30 to 70 mole % of R⁶ are phenyl groups.

In some examples, resin-linear and/or high-phenyl-T compositions can be considered “hydrosilylation cure compositions.”

As used herein, the term “silicone sealant composition” includes polysiloxane sealants, such as those disclosed in U.S. Pat. Nos. 4,962,152; 5,264,603; 5,373,079; and 5,425,947, the entireties of all of which are incorporated by reference as if fully set forth herein. It also includes XIAMETER® (Dow Corning, Midland, Mich.) brand acetoxy, alkoxy, and oxime sealants. Other silicone sealant compositions include siloxane high consistency rubber compositions such as Sotefa 70M, available from Dow Corning, Midland, Mich.

As used herein, the term “polyurea-polysiloxane composition” includes, but is not limited to, multiblock copolymers including polyurea and polysiloxane segments. In some examples, polyurea-polysiloxane compositions include polyurea-PDMS compositions including GENIOMER® (Wacker Chemie AG, Munich Germany), TECTOSIL® (Wacker Chemie AG, Munich Germany), and the like. The polyurea-polysiloxane compositions can also contain additional polymeric segments, such as polypropylene oxide soft segments. Polyurea-polysiloxane compositions also includes the polyurea-polysiloxane compositions disclosed in Published U.S. Patent Appl. No. 2010/0047589, the entirety of which is incorporated by reference as if fully set forth herein.

As used herein, the term “MQ/polysiloxane composition” includes compositions including MQ-type hot melt compositions containing an MQ silicone resin (MQ-1600 Solid Resin, MQ-1601 Solid Resin, 7466 Resin, and 7366 Resin, all of which are commercially available from Dow Corning Corporation, as well as MQ resins disclosed in U.S. Pat. No. 5,082,706, which is incorporated by reference as if fully set forth herein) and a polyorganosiloxane, such as polydimethylsiloxane (PDMS). Such compositions include, but are not limited to, Dow Corning® Q2-7735 Adhesive, and InstantGlaze Assembly Sealant

MQ-type compositions also include compositions, such as those disclosed in Published PCT Appl. No. WO2010/138221 and Published U.S. Patent Appl. No. 2012/0065343 (both incorporated herein by reference in their entirety) comprising a low viscosity polydiorganosiloxane having an average of at least two aliphatically unsaturated organic groups per molecule and having a viscosity of up to 12,000 mPa-s, and a high viscosity polydiorganosiloxane having an average of at least two aliphatically unsaturated organic groups per molecule and having a viscosity of at least 45,000 mPa-s; a silicone resin having an average of at least two aliphatically unsaturated organic groups per molecule; and a crosslinker having an average, per molecule, of at least two silicon bonded hydrogen atoms.

Other MQ-type compositions include those disclosed in U.S. Pat. No. 5,708,098, the entirety of which is incorporated by reference as if fully set forth herein. Briefly, the compositions disclosed in the '098 patent include containing macromolecular polymers comprised primarily of R₃SiO_{1/2} and SiO_{4/2} units (the M and Q units, respectively) wherein R is as defined in the '098 patent as a functional or nonfunctional, substituted or unsubstituted organic radical. These macromolecular polymers are referred to as “MQ-resins” or “MQ silicone resins.” The MQ-type compositions disclosed in the '098 patent, may, in some examples, include a number of R₂SiO_{2/2} and RSiO_{3/2} units, respectively referred to as D and T units. MQ silicone resins are generally produced in such a manner that the resin macromolecules are dissolved in a solvent, which is typically, but not always, an aromatic solvent. Some of the embodiments of the '098 patent are directed to solventless, thermoplastic silicone pellets prepared by blending silicone resins of the MQ-type predominantly with linear silicone fluids, such as polydimethylsiloxane liquids and gums, to substantially homogeneity. The blends are heated to a predetermined compression-forming temperature, compression-formed to a densified mass and shaped into a pellet form. The composition of the pellets is balanced such that the pellets exhibit plastic flow at the predetermined compression-forming temperature and resist agglomeration at temperatures at or below a predetermined maximum storage temperature.

Other MQ-type compositions are disclosed in Published U.S. Patent Appl. No. 2011/0104506, which is incorporated by reference as if fully set forth herein. Briefly, the MQ-type compositions disclosed in the '506 application hot melt adhesive composition containing (1) a silicone resin having a silanol content of less than 2 wt % and comprised of M and Q units; (2) an organopolysiloxane comprised of difunctional units, D, and certain terminal units; (3) a silane crosslinker; and (4) a catalyst. Other MQ-type compositions are disclosed in WO2007/120197, the entirety of which is incorporated by reference as if fully set forth herein.

As used herein, the term “MQ/X-diorganosiloxane composition” includes, but is not limited to, compositions including MQ-type hot melt compositions containing an MQ silicone resin, and an X-diorganosiloxane, where X includes, but is not limited to, any organic polymer. In some examples, the organic polymer portion of the X-diorganosiloxane contains blocks, diblocks, triblocks, multi-blocks, and segmented portions containing one or more organic polymers (e.g., an acrylic polymer, a polycarbonate, an alkylene polymer or an alkylene-acrylic copolymer). In some examples, the diorganosiloxane portion of the X-diorganosiloxane contains blocks, diblocks, triblocks, multi-blocks, and segmented portions containing one or more diorganosiloxanes (e.g., PDMS, PhMe or Ph₂/Me₂). A non-limiting example of an MQ/X-diorganosiloxane includes an MQ-resin/PS-PDMS composition.

As used herein, the term “MQ-resin/PS-PDMS composition” includes polystyrene-polydimethylsiloxane compositions (e.g., trimethylsiloxy-terminated poly(styrene-block-dimethylsiloxane) copolymer having a weight average molecular weight (M_{w}) of 45,500 and a polydispersity of 1.15 and having a 31,000 g/mole styrene block and a 15,000 g/mole dimethylsiloxane block; available from Polymer Source, Inc.) containing an MQ-resin. Examples of such MQ-resin/PS-PDMS compositions are disclosed in WO 2012/071330, the entirety of which is incorporated by reference as if fully set forth herein.

Still other MQ-type compositions include those disclosed in Published U.S. Patent Appl. No. 2012/0125436, which is incorporated by reference as if fully set forth herein. Such compositions comprise thermoplastic elastomers comprising at least one silicone ionomer (i.e., polymers in which the bulk properties are governed by ionic interactions in discrete regions of the material).

As used herein, the term “polyimide-polysiloxane composition” includes compositions including polyimide polysiloxanes such as those disclosed in U.S. Pat. Nos. 4,795,680; 5,028,681; 5,317,049; and the like, the entireties of which are incorporated by reference as if fully set forth herein. Polyimide-polysiloxane compositions also include compositions containing PDMS-containing polyimide copolymers including, but not limited to, imide-siloxane compositions containing imide-siloxanes of the formula:

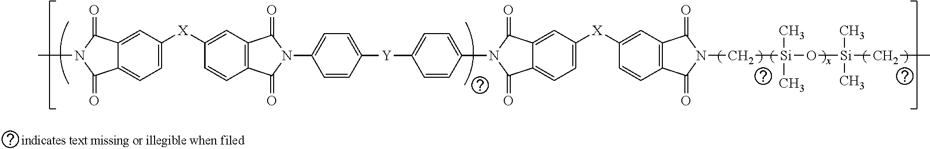

such as those disclosed in Rogers, M. E.; et al., J. of Polymer Sci. A: Poly Chem 32: 2663 (1994); and Contemporary Topics in Polymer Science 47-55 (Salamone, J. S and. Riffle, J. S. eds., New York: Plenum Press 1992), the entireties of which are incorporated by reference as if fully set forth herein.

As used herein, the term “polycarbonate-polysiloxane composition” includes, but is not limited to, compositions including polycarbonate-polysiloxane compositions such as those disclosed in U.S. Pat. Nos. 7,232,865; 6,870,013; 6,630,525; 5,932,677; 5,932,677; and the like, the entireties of which are incorporated by reference as if fully set forth herein. Polycarbonate-polysiloxane compositions also include compositions containing polycarbonate-polysiloxanes such as those disclosed in Contemporary Topics in Polymer Science 265-288 (Culbertson, ed., Plenum 1989); Chen, X., et al., Macromolecules 26: 4601 (1993); Dwight, D. W. et al., Journal of Electron Spectroscopy and Related Phenomena 52: 457 (1990); and Furukawa, N, et al., J. Adhes. 59: 281 (1996), the entireties of which are incorporated by reference as if fully set forth herein.

As used herein, the term “polyurethane-polysiloxane composition,” includes, but is not limited to, compositions including polyurethane-polysiloxane compositions such as those disclosed in U.S. Pat. Nos. 6,750,309; 4,836,646; 4,202,807; and the like, the entireties of which are incorporated by reference as if fully set forth herein. Polyurethane-polysiloxane compositions also include compositions containing polyurethane-polysiloxanes such as those disclosed in Chen, X., et al., Macromolecules 26: 4601 (1993); Dwight, D. W. et al., Journal of Electron Spectroscopy and Related Phenomena 52: 457 (1990), the entireties of which are incorporated by reference as if fully set forth herein.

As used herein, the term “polyacrylate-polysiloxane composition” include, but are not limited to polyacrylate-modified polysiloxanes such as those disclosed in U.S. Pat. Nos. 8,076,440; and 7,230,051; as well as mixtures of polyacrylate resins and siloxane-containing copolymers, such as those disclosed in U.S. Pat. No. 4,550,4139, the entireties of which are incorporated by reference as if fully set forth herein.

As used herein the term “polyisobutylene-polysiloxane composition,” includes, but is not limited to, compositions including polyisobutylene-polysiloxane compositions such as those disclosed in EP0969032, and the like, the entirety of which is incorporated by reference as if fully set forth herein.

Other compositions contemplated for use as encapsulants include ethylene-vinyl acetate (EVA) copolymers and polyvinyl fluoride films (e.g., TEDLAR®, Dupont, Wilmington, Del.).

Also contemplated herein are encapsulants containing perfluorinated polymer compositions having alkenyl groups and a perfluoroether backbone, where the alkenyl groups can react with a fluorinated organohydrogensiloxane via a hydrosilylation cure mechanism in the presence of a platinum catalyst. Such compositions are disclosed in Published U.S. Appl. No. US2009/0284149 and JP2010-123769, the entireties of which are incorporated by reference as if fully set forth herein. The compositions disclosed in the '149 and '769 applications also contain silica having a specific surface area.

Resin-linear compositions are known in the art and are described, for example, in Published U.S. Appl. Nos. 2013/0168727; 2013/0171354; 2013/0245187; 2013/0165602; and 2013/0172496, all of which are expressly incorporated by reference as if fully set forth herein. In some specific examples, resin-linear compositions contain resin-linear organosiloxane block copolymers containing: 40 to 90 mole percent units of the formula [R¹₂SiO_{2/2}], 10 to 60 mole percent units of the formula [R²SiO_{3/2}], 0.5 to 25 mole percent silanol groups, wherein R¹ and R² are as defined herein; wherein the units [R¹₂SiO_{2/2}] are arranged in linear blocks having an average of from 10 to 400 [R¹₂SiO_{2/2}] units per linear block, the units [R²SiO_{3/2}] are arranged in non-linear blocks having a molecular weight of at least 500 g/mole, at least 30% of the non-linear blocks are crosslinked with each other and are predominately aggregated together in nano-domains, each linear block is linked to at least one non-linear block; and the organosiloxane block copolymer has a weight average molecular weight of at least 20,000 g/mole, and is a solid at 25° C.

When solid compositions are formed from curable compositions of resin-linear organosiloxane block copolymers described herein, which, in some embodiments also contain an organosiloxane resin (e.g., free resin that is not part of the block copolymer), the organosiloxane resin also predominately aggregates within the nano-domains.

Curable silicone compositions formed from curable compositions of resin-linear organosiloxane block copolymers can also include a cure catalyst. The cure catalyst may be chosen from any catalyst known in the art to effect (condensation) cure of organosiloxanes, such as various tin or titanium catalysts. Condensation catalysts can be any condensation catalyst typically used to promote condensation of silicon bonded hydroxy (silanol) groups to form Si—O—Si linkages. Examples include, but are not limited to, amines, complexes of lead, tin, titanium, zinc, and iron.

Solid composition of this disclosure formed from curable compositions of resin-linear organosiloxane block copolymers can include phase separated “soft” and “hard” segments resulting from blocks of linear D units and aggregates of blocks of non-linear T units, respectively. These respective soft and hard segments may be determined or inferred by differing glass transition temperatures (T_{g}). Thus a linear segment may be described as a “soft” segment typically having a low T_{g}, for example less than 25° C., alternatively less than 0° C., or alternatively even less than −20° C. The linear segments typically maintain “fluid” like behavior in a variety of conditions. Conversely, non-linear blocks may be described as “hard segments” having higher T_{g} values, for example greater than 30° C., alternatively greater than 40° C., or alternatively even greater than 50° C.

An advantage of the present resin-linear organopolysiloxanes block copolymers can be that they can be processed several times, because the processing temperature (T_{processing}) is less than the temperature required to finally cure (T_{cure}) the organosiloxane block copolymer, i.e., T_{processing}<T_{cure}. However the organosiloxane copolymer will cure and achieve high temperature stability when T_{processing} is taken above T_{cure}. Thus, the present resin-linear organopolysiloxanes block copolymers offer the significant advantage of being “re-processable” in conjunction with the benefits typically associated with silicones, such as; hydrophobicity, high temperature stability, moisture/UV resistance.

In some embodiments, curable silicone compositions comprising resin-linear organopolysiloxanes block copolymers also include an organic solvent. In some embodiments, the term “curable silicone composition” also includes a combination of the solid composition in, or combined with, a solvent. The organic solvent, in some embodiments, is an aromatic solvent, such as benzene, toluene, or xylene. In some embodiments, the solvent substantially (e.g., completely or entirely) dissolves the organosiloxane block copolymer described herein.

Curable compositions described herein that comprise resin-linear organopolysiloxanes block copolymers may further contain an organosiloxane resin (e.g., free resin that is not part of the block copolymer). The organosiloxane resin present in these compositions typically will be the organosiloxane resin used to prepare the organosiloxane block copolymer. Thus, the organosiloxane resin may comprise at least 60 mol % of [R²SiO_{3/2}] siloxy units in its formula (e.g., at least 70 mol % of [R²SiO_{3/2}] siloxy units, at least 80 mole % of [R²SiO_{3/2}] siloxy units, at least 90 mole % of [R²SiO_{3/2}] siloxy units, or 100 mole % of [R²SiO_{3/2}] siloxy units; or 60-100 mole % [R²SiO_{3/2}] siloxy units, 60-90 mole % [R²SiO_{3/2}] siloxy units or 70-80 mole % [R²SiO_{3/2}] siloxy units), where each R² is independently a C₁ to C₂₀ hydrocarbyl. Alternatively, the organosiloxane resin is a silsesquioxane resin, or alternatively a phenyl silsesquioxane resin.

When the curable composition includes an organosiloxane block copolymer, organic solvent, and optional organosiloxane resin, the amounts of each component may vary. The amount of the organosiloxane block copolymers, organic solvent, and optional organosiloxane resin in the present curable composition may vary. The curable composition of the present disclosure may contain: 40 to 80 weight % of an organosiloxane block copolymer as described herein (e.g., 40 to 70 weight %, 40 to 60 weight %, 40 to 50 weight %); 10 to 80 weight % of an organic solvent (e.g., 10 to 70 weight %, 10 to 60 weight %, 10 to 50 weight %, 10 to 40 weight %, 10 to 30 weight %, 10 to 20 weight %, 20 to 80 weight %, 30 to 80 weight %, 40 to 80 weight %, 50 to 80 weight %, 60 to 80 weight %, or 70 to 80 weight; and 5 to 40 weight %); and organosiloxane resin (e.g., 5 to 30 weight %, 5 to 20 weight %, 5 to 10 weight %, 10 to 40 weight %, 10 to 30 weight %, 10 to 20 weight %, 20 to 40 weight % or 30 to 40 weight %); such that the sum of the weight % of these components does not exceed 100%.

In some examples, the optical assembly of the embodiments described herein comprises a first layer, a second layer, and a third layer, wherein any one of the layers is cured. The mechanism by which the first layer is cured may be the same or different than the mechanism by which the second and/or third layers are/is cured. Curing mechanisms suitable for curing the layers independently include, but are not limited to a hot melt or heat cure, moisture cure, a hydrosilylation cure (as described below), a condensation cure, peroxide/radical cure, photo cure or a click chemistry-based cure. Click chemistry-based cure involves, in some examples, metal-catalyzed (copper or ruthenium) reactions between an azide and an alkyne or a radical-mediated thiol-ene reactions. Other cure mechanisms suitable for curing the layers independently include, but are not limited to peroxide vinyl-CH₃ cure; acrylic radical cure; alkyl borane cure; and epoxy-amine/phenolic cure.

“Click Chemistry” is a term that was introduced by K. B. Sharpless in 2001 to describe reactions that are high yielding, wide in scope, create byproducts that can be removed without chromatography, are stereospecific, simple to perform, and can be conducted in removable or benign solvents. Several types of reaction have been identified that fulfill these criteria, thermodynamically-favored reactions that lead specifically to one product, such as nucleophilic ring opening reactions of epoxides and aziridines, non-aldol type carbonyl reactions, such as formation of hydrazones and heterocycles, additions to carbon-carbon multiple bonds, such as oxidative formation of epoxides and Michael Additions, and cycloaddition reactions. See, e.g., Rasmussen, L. K., et al., Org. Lett 9: 5337-5339, which is incorporated by reference as if fully set forth herein, for an example of the application of click-chemistry.

This disclosure also provides a method of forming the optical assembly. The method includes the step of combining the light emitting diode and a layer (e.g., first layer 106) to form the optical assembly. The step of combining is not particularly limited and may be include, or be further defined as, disposing the light emitting diode and the layer next to each other or on top of each other, and/or in direct or in indirect contact with each other. For example, the layer may be disposed on and in direct contact with the light emitting diode. Alternatively, the layer may be disposed on, but separated from and not in direct contact with, the light emitting diode yet may still be disposed on the light emitting diode.

The layer may be heated to flow, melted, pressed, (vacuum) laminated, compression molded, injection transfer molded, calendared, hot-embossed, injection molded, extruded, or any other process step that changes the layer from a solid to a liquid or to a softened solid.

The liquid or softened layer may then be applied to the light emitting diode by any one or more of the aforementioned techniques, via spraying, pouring, painting, coating, dipping, brushing, or the like.

In one example, the step of combining is further defined as melting the layer such that the solid composition is disposed on and in direct contact with the light emitting diode. In another example, the step of combining is further defined as melting the layer such that the layer is disposed on and in indirect contact with the light emitting diode. In still another example, the method further includes the step of providing a solution of the solid composition in a solvent, e.g., dissolved or partially dissolved in the solvent. In an even further example, the method includes the step of removing the solvent to form the solid composition to form the layer prior to the step of combining the light emitting diode and the layer. In still another example, the method further includes the step of forming the solid composition into the layer subsequent to the step of removing the solvent and prior to the step of combining the light emitting diode and the layer.

In other embodiments, the method includes the step of curing the solid composition, e.g., via a condensation reaction, a free radical reaction, or a hydrosilylation reaction. Any catalysts, additives, and the like may be utilized in the step of curing. For example, acidic or basic condensation catalysts may be utilized. Alternatively, hydrosilylation catalysts, such as platinum catalysts, may be utilized. In one example, the step of curing occurs at a temperature higher than the melting temperature of the solid composition. Alternatively, the step of curing may occur at approximately the melting temperature, or below the melting temperature, of the layer.

### EXAMPLES

The following examples are included to demonstrate specific embodiments of the invention. However, those of skill in the art should, in light of the present disclosure, appreciate that many changes can be made in the specific embodiments which are disclosed and still obtain a like or similar result without departing from the spirit and scope of the invention.

### Example 1

A 500 mL 4 neck round bottom flask was loaded with Dow Corning 217 Flake (45.0 g, 0.329 moles Si) and toluene (Fisher Scientific, 70.38 g). The flask was equipped with a thermometer, Teflon stir paddle, and a Dean Stark apparatus attached to a water-cooled condenser. A nitrogen blanket was applied, Dean Stark was prefilled with toluene, and an oil bath was used for heating. The reaction mixture was heated at reflux for 30 min. After cooling the reaction mixture to 108° C., a solution of diacetoxy terminated PhMe siloxane was added quickly. The diacetoxy terminated PhMe siloxane was prepared by adding a 50/50 wt % MTA/ETA (1.21 g, 0.00523 moles Si) mixture to a solution of 140 dp silanol terminated PhMe siloxane (55.0 g, 0.404 moles Si) dissolved in toluene (29.62 g). The solution was mixed for 2 hrs at room temperature under a nitrogen atmosphere. After the diacetoxy terminated PhMe siloxane was added, the reaction mixture was heated at reflux for 2 hrs. At this stage 50/50 wt % MTA/ETA (7.99 g, 0.0346 moles Si) was added at 108° C. The reaction mixture was heated at reflux for an additional 1 hr. It was cooled to 90° C. and then DI water (12 mL) was added. Temperature was increased to reflux and the water was removed by azeotropic distillation. Reaction mixture was cooled again to 90° C. and more DI water (12 mL) was added. It was heated up to reflux and water was removed again. Some toluene (56.9 g) was then removed by distillation to increase the solids content. Material was cooled to room temperature and then pressure filtered through a 5.0 μm filter. Cast sheets (made by pouring the solution in a chase and evaporating the solvent) were optically clear.

### Example 2

A 3 L 4 neck round bottom flask was loaded with Dow Corning 217 Flake (378.0 g, 2.77 moles Si) and toluene (Fisher Scientific, 1011.3 g). The flask was equipped with a thermometer, Teflon stir paddle, and a Dean Stark apparatus attached to a water-cooled condenser. A nitrogen blanket was applied, Dean Stark was prefilled with toluene, and an oil bath was used for heating. The mixture was heated at reflux for 30 minutes. A bottle was loaded with silanol terminated PDMS (462.0 g siloxane, 6.21 mols Si) and toluene (248.75 g). It was capped with 50/50 methyl triacetoxysilane/ethyl triacetoxysilane (MTA/ETA) (31.12 g, 0.137 mols Si) in a glove box (same day) under nitrogen by adding the 50/50 MTA/ETA to the PDMS and mixing at room temperature for 1 h. The capped PDMS was added to the 217 flake solution quickly and heated to reflux for 2 hrs. The solution was cooled to 108° C. and 28.4 g of MTA/ETA 5/5 ratio was added, followed by reflux for 1 h. The solution was cooled to 90° C. and 89.3 g of DI water was added. Temperature was increased to reflux and the water was removed by azeotropic distillation. Toluene was distilled off (884.6 g) to increase the solids content to about 70%. Cast sheets (made by pouring the solution in a chase and evaporating the solvent) were optically clear.

### Example 3: Construction of a Multi-Layer Film with Resin Interlayer

The composition of Example 1 was dispensed to a speed mixer cup followed by 20 ppm 1,8-Diazabicyclo[5.4.0]undec-7-ene (DBU) catalyst, mixed two times for 30 seconds at 3000 rpm using a DAC150 FV dual axis speed mixer by FlackTek Inc. Then 30 wt. % phosphor (NYAG 4454-S phosphor; ˜100 μm) was added, mixed again two times for 30 seconds at 3000 rpm, then coated as described below to make a silicone hot melt film. The composition of Example 2 was dispensed into a speed mixer cup followed by 10 ppm DBU catalyst and mixed two times for 30 seconds at 3000 rpm, then coated as described below to make another silicone hot melt film.

The silicone hot melt film made from the composition of Example 1, containing 30 wt. % NYAG 4454-S phosphor (“film 1”) and the silicone hot melt film made from the composition of Example 2 (“film 2”) were each coated on fluorinated ethylene propylene (FEP) film FEP using a Zehntner ZUA 200 universal applicator and Zehntner automated coating table with vacuum plate, such that each film was about ˜100 μm thick. The coated films were then placed into a convection oven for 30 minutes at 70° C. to remove the toluene. Once the solvent was removed from the films, a layer of resin (XIAMETER® resin RSN-840) was applied to the surface of each film. This consisted of air brushing a 50% solution of resin in toluene using the Badger Universal Model 360 Air Brush at 40 psi. Multiple passes were made to cover one side of each hot melt film. The films were then placed back into a convection oven for 15 minutes at 70° C.

Once the films were prepared, the two films were vacuum laminated such that the resin coatings facing each other to make a three-layer structure having a resin interlayer located between the two films. Specifically, the three-layer structure was sandwiched between FEP films, placed into the laminator chamber at 50° C., then closed and vacuum applied for 1 minute before ramping to 130° C. The silicone bladder was then applied once temperature reached 80° C., putting atmospheric pressure onto the structure. Once the temperature reached 130° C. it was held for 5 minutes. The temperature was then ramped to 160° C. and held again for 5 minutes. The bladder was released, the vacuum opened, the samples removed and placed into a convection oven for 3 hours at 160° C. The film made from the composition of Example 1 had a refractive index of 1.557. The film made from the composition of Example 2 had a refractive index of 1.466.

A series of four samples were prepared. Sample 1 contains no interlayer located between the two films. Sample 2 also lacks an interlayer, but both films were air brushed with toluene to roughen the surface of each film, before the two films were laminated to obtain a two-layer structure. Samples 3 and 4 contained a resin interlayer located between the two films. The interlayer was formed by air brushing with ˜3 passes to form a thin layer in Sample 3 and ˜9 passes to form a thicker layer in Sample 4.

Adhesion testing was conducted on Samples 5, 6, and 7 after lamination. These samples were prepared in the same as Samples 1, 2, and 3, respectively, except roughened 1.75 mil polyethylene (PET) was used to sandwich the structure instead of FEP film. The PET was used to give the films some support and create tabs that could be placed into grips of a testing instrument. The TA. HD plus Texture Analyzer was used to test for adhesion of the prepared multilayer films. The samples were pulled at 4.8 mm/min using a 5 kg load cell and mechanical grips. The PET was used primarily to support the 100 μm films, which were mechanically too weak by themselves to be used in the Texture Analyzer instrument without risk of being torn.

The PET was also roughened to help with the adhesion of the films to the PET. Test specimens were 12 mm wide×40 mm long and pulled to failure. The test showed that the addition of the resin interlayer significantly increased the adhesion between the two films, as shown in Table 1.

TABLE 1

| | Average Adhesion | |
|---|---|---|
| Sample | Force (3x; g) | Failure Mode |
| 5 | 345 | Film 2/film 1 and film 1/PET |
| 6 | 369 | Film 2/film 1 |
| 7 | 511 | Film 2/PET and film 1/PET |

One or more of the values described above may vary by ±5%, ±10%, ±15%, ±20%, ±25%, etc. so long as the variance remains within the scope of the disclosure. Unexpected results may be obtained from each member of a Markush group independent from all other members. Each member may be relied upon individually and or in combination and provides adequate support for specific embodiments within the scope of the appended claims. The subject matter of all combinations of independent and dependent claims, both singly and multiply dependent, is herein expressly contemplated. The disclosure is illustrative including words of description rather than of limitation. Many modifications and variations of the present disclosure are possible in light of the above teachings, and the disclosure may be practiced otherwise than as specifically described herein.

In this document, the terms “a,” “an,” or “the” are used to include one or more than one unless the context clearly dictates otherwise. The term “or” is used to refer to a nonexclusive “or” unless otherwise indicated. In addition, the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section. Furthermore, all publications, patents, and patent documents referred to in this document are incorporated by reference herein in their entirety, as though individually incorporated by reference. In the event of inconsistent usages between this document and those documents so incorporated by reference, the usage in the incorporated reference should be considered supplementary to that of this document; for irreconcilable inconsistencies, the usage in this document controls.

The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more. In some embodiments, the term “substantially” can encompass “completely” or “entirely.”

The present invention provides for the following exemplary embodiments, the numbering of which is not to be construed as designating levels of importance:

Embodiment 1 relates to an encapsulant film comprising:
a first layer comprising a first resin-linear organosiloxane block copolymer comprising resin blocks comprising units of the formula [R¹₂SiO_{2/2}] and units of the formula [R²SiO_{3/2}] and linear blocks, the first layer having a first major surface and a second major surface;
a second layer comprising a second resin-linear organosiloxane block copolymer comprising resin blocks comprising units of the formula [R¹₂SiO_{2/2}] and units of the formula [R²SiO_{3/2}] and linear blocks, the second layer having a first major surface and a second major surface; and
a third layer comprising an organosiloxane resin comprising units of the formula [R¹₂SiO_{2/2}] and units of the formula [R²SiO_{3/2}], the third layer in direct contact with the second major surface of the first layer and the first major surface of the second layer;
wherein:
R¹ is independently a C₁ to C₃₀ hydrocarbyl, and
R² is independently a C₁ to C₂₀ hydrocarbyl.

Embodiment 2 relates to the encapsulant film of Embodiment 1, wherein:
about 20 to about 100 mole percent of at least one of the R¹ groups of the units of the formula [R¹₂SiO_{2/2}] and R² groups of the units of the formula [R²SiO_{3/2}] of the resin blocks of at least one of the first resin-linear organosiloxane block copolymer of the first layer and the second resin-linear organosiloxane block copolymer of the second layer are C₆-C₁₆ aryl groups; and
about 20 to about 100 mole percent of at least one of the R¹ groups of the units of the formula [R¹₂SiO_{2/2}] and R² groups of the units of the formula [R²SiO_{3/2}] of the organosiloxane resin of the third layer are C₆-C₁₆ aryl groups.

Embodiment 3 relates to the encapsulant film of Embodiment 1, wherein:
about 20 to about 100 mole percent of at least one of the R¹ groups of the units of the formula [R¹₂SiO_{2/2}] and R² groups of the units of the formula [R²SiO_{3/2}] of the resin blocks of at least one of the first resin-linear organosiloxane block copolymer of the first layer and the second resin-linear organosiloxane block copolymer of the second layer are C₁-C₆ alkyl groups; and
about 20 to about 100 mole percent of at least one of the R¹ groups of the units of the formula [R¹₂SiO_{2/2}] and R² groups of the units of the formula [R²SiO_{3/2}] of the organosiloxane resin of the third layer are C₁-C₆ alkyl groups.

Embodiment 4 relates to the encapsulant film of Embodiments 1-3, wherein at least one of the first resin-linear organosiloxane block copolymer and the second resin-linear organosiloxane block copolymer comprises resin-linear organosiloxane block copolymers comprising:
40 to 90 mole percent units of the formula [R¹₂SiO_{2/2}],
10 to 60 mole percent units of the formula [R²SiO_{3/2}],
0.5 to 25 mole percent silanol groups;
wherein:
R¹ is independently a C₁ to C₃₀ hydrocarbyl,
R² is independently a C₁ to C₂₀ hydrocarbyl;
the units [R¹₂SiO_{2/2}] are arranged in linear blocks having an average of from 10 to 400 [R¹₂SiO_{2/2}] units per linear block,
the units [R²SiO_{3/2}] are arranged in non-linear blocks having a molecular weight of at least 500 g/mole,
at least 30% of the non-linear blocks are crosslinked with each other and are predominately aggregated together in nano-domains,
each linear block is linked to at least one non-linear block; and
the resin-linear organosiloxane block copolymer has a weight average molecular weight of at least 20,000 g/mole and is a solid at 25° C.

Embodiment 5 relates to the encapsulant film of Embodiment 4, wherein R² is phenyl.

Embodiment 6 relates to the encapsulant film of Embodiments 4-5, wherein R¹ is methyl or phenyl.

Embodiment 7 relates to the encapsulant film of Embodiments 4-6, wherein the units of the formula [R¹₂SiO_{2/2}] have the formula [(CH₃)(C₆H₅)SiO_{2/2}] or [(CH₃)₂SiO_{2/2}].

Embodiment 8 relates to the encapsulant film of Embodiments 1-7, wherein the organosiloxane resin comprises at least 60 mol % of [R²SiO_{3/2}] siloxy units in its formula.

Embodiment 9 relates to the encapsulant film of Embodiment 8, wherein each R² is independently a C₁ to C₂₀ hydrocarbyl.

Embodiment 10 relates to the encapsulant film of Embodiments 1-9, wherein the organosiloxane resin is a silsesquioxane resin.

Embodiment 11 relates to the encapsulant film of Embodiments 1-10, wherein the organosiloxane resin is a phenyl silsesquioxane resin.

Embodiment 12 relates to the encapsulant film of Embodiments 1-11, wherein the thickness of the encapsulant film is from about 0.5 μm to about 5000 μm.

Embodiment 13 relates to the encapsulant film of Embodiments 1-12, wherein at least one of the first layer or the second layer comprises one or more phosphors.

Embodiment 14 relates to an optical assembly, comprising an optical device comprising an optical surface; and the encapsulant film of Embodiments 1-13, wherein the encapsulant film substantially or entirely covers the optical surface.

Embodiment 15 relates to a method for making an optical assembly, comprising: substantially or entirely covering an optical surface of an optical device with the encapsulant film of embodiments 1-13.

Embodiment 16 relates to the method of Embodiment 15, further comprising pre-forming the encapsulant film before the covering step.

Embodiment 17 relates to the method of Embodiment 16, wherein the pre-forming comprises:
forming the first layer;
forming the second layer;
applying an organosiloxane resin composition to at least one of the second major surface of the first layer and the first major surface of the second layer;
contacting the second major surface of the first layer, the applied organosiloxane resin composition, and the first major surface of the second layer together to form the third layer between the second major surface of the first layer and the first major surface of the second layer and form a layered polymeric structure; and
laminating or compression molding the layered polymeric structure.

Embodiment 18 relates to the method of Embodiment 17, further comprising curing at least one of the first layer, second layer, and the third layer.

Embodiment 19 relates to the method of Embodiment 18, wherein at least one of the first layer, second layer, and third layer has the same or a different curing mechanism than the curing mechanism of at least one of the other of the first, second, and third layer.

Embodiment 20 relates to the method of Embodiment 19, wherein the curing mechanism comprises a hot melt cure, moisture cure, a hydrosilylation cure, a condensation cure, peroxide cure or a click chemistry-based cure mechanism.

1. An encapsulant film comprising:
a first layer comprising a first resin-linear organosiloxane block copolymer comprising resin blocks comprising units of the formula [R¹₂SiO_{2/2}] and units of the formula [R²SiO_{3/2}] and linear blocks, the first layer having a first major surface and a second major surface;
a second layer comprising a second resin-linear organosiloxane block copolymer comprising resin blocks comprising units of the formula [R¹₂SiO_{2/2}] and units of the formula [R²SiO_{3/2}] and linear blocks, the second layer having a first major surface and a second major surface; and
a third layer comprising an organosiloxane resin comprising units of the formula [R¹₂SiO_{2/2}] and units of the formula [R²SiO_{3/2}], the third layer in direct contact with the second major surface of the first layer and the first major surface of the second layer;
wherein:
R¹ is independently a C₁ to C₃₀ hydrocarbyl, and
R² is independently a C₁ to C₂₀ hydrocarbyl.

2. The encapsulant film of claim 1, wherein:
about 20 to about 100 mole percent of at least one of the R¹ groups of the units of the formula [R¹₂SiO_{2/2}] and R² groups of the units of the formula [R²SiO_{3/2}] of the resin blocks of at least one of the first resin-linear organosiloxane block copolymer of the first layer and the second resin-linear organosiloxane block copolymer of the second layer are C₆-C₁₆ aryl groups; and
about 20 to about 100 mole percent of at least one of the R¹ groups of the units of the formula [R¹₂SiO_{2/2}] and R² groups of the units of the formula [R²SiO_{3/2}] of the organosiloxane resin of the third layer are C₆-C₁₆ aryl groups.

3. The encapsulant film of claim 1, wherein:
about 20 to about 100 mole percent of at least one of the R¹ groups of the units of the formula [R¹₂SiO_{2/2}] and R² groups of the units of the formula [R²SiO_{3/2}] of the resin blocks of at least one of the first resin-linear organosiloxane block copolymer of the first layer and the second resin-linear organosiloxane block copolymer are C₁-C₆ alkyl groups; and
about 20 to about 100 mole percent of at least one of the R¹ groups of the units of the formula [R¹₂SiO_{2/2}] and R² groups of the units of the formula [R²SiO_{3/2}] of the organosiloxane resin of the third layer are C₁-C₆ alkyl groups.

4. The encapsulant film of claim 1, wherein at least one of the first resin-linear organosiloxane block copolymer and the second resin-linear organosiloxane block copolymer comprises resin-linear organosiloxane block copolymers comprising:
40 to 90 mole percent units of the formula [R¹₂SiO_{2/2}],
10 to 60 mole percent units of the formula [R²SiO_{3/2}],
0.5 to 25 mole percent silanol groups;
wherein:
R¹ is independently a C₁ to C₃₀ hydrocarbyl,
R² is independently a C₁ to C₂₀ hydrocarbyl;
the units [R¹₂SiO_{2/2}] are arranged in linear blocks having an average of from 10 to 400 [R¹₂SiO_{2/2}] units per linear block,
the units [R²SiO_{3/2}] are arranged in non-linear blocks having a molecular weight of at least 500 g/mole,
at least 30% of the non-linear blocks are crosslinked with each other and are predominately aggregated together in nano-domains,
each linear block is linked to at least one non-linear block; and
the resin-linear organosiloxane block copolymer has a weight average molecular weight of at least 20,000 g/mole and is a solid at 25° C.

5. The encapsulant film of claim 1, wherein the organosiloxane resin comprises at least 60 mol % of [R²SiO_{3/2}] siloxy units in its formula wherein each R² is independently a C₁ to C₂₀ hydrocarbyl.

6. (canceled)

7. The encapsulant film of claim 1, wherein the organosiloxane resin is a silsesquioxane resin.

8. The encapsulant film of claim 7, wherein the organosiloxane resin is a phenyl silsesquioxane resin.

9. The encapsulant film of claim 1, wherein the thickness of the encapsulant film is from about 0.5 μm to about 5000 μm.

10. The encapsulant film of claim 1, wherein at least one of the first layer or the second layer comprises one or more phosphors.

11. An optical assembly, comprising an optical device comprising an optical surface; and the encapsulant film of claim 1, wherein the encapsulant film substantially or entirely covers the optical surface.

12. A method for making an optical assembly, comprising: substantially or entirely covering an optical surface of an optical device with the encapsulant film of claim 1.

13. The method of claim 12, further comprising pre-forming the encapsulant film before the covering step.

14. The method of claim 13, wherein the pre-forming comprises:
forming the first layer;
forming the second layer;
applying an organosiloxane resin composition to at least one of the second major surface of the first layer and the first major surface of the second layer;
contacting the second major surface of the first layer, the applied organosiloxane resin composition, and the first major surface of the second layer together to form the third layer between the second major surface of the first layer and the first major surface of the second layer and form a layered polymeric structure; and
laminating or compression molding the layered polymeric structure.

15. The method of claim 14, further comprising curing at least one of the first layer, second layer, and the third layer.

16. The method of claim 15, wherein at least one of the first layer, second layer, and third layer has the same or a different curing mechanism than the curing mechanism of at least one of the other of the first, second, and third layer.
